(19) United States
(12) Patent Application Publication
(10) Pub. No.: US 2025/0331154 A1
(43) Pub. Date: Oct. 23, 2025

(54) VERTICAL GATE-ALL-AROUND TRANSISTOR AND MANUFACTURING METHOD THEREOF, AND CAPACITOR-FREE MEMORY AND MANUFACTURING METHOD THEREOF

(71) Applicants: Beijing Superstring Academy of Memory Technology, Beijing (CN); INSTITUTE OF MICROELECTRONICS, CHINESE ACADEMY OF SCIENCES, Beijing (CN)

(72) Inventors: Gaobo XU, Beijing (CN); Zhiyu SONG, Beijing (CN); Gangping YAN, Beijing (CN); Shangbo YANG, Beijing (CN); Huaxiang YIN, Beijing (CN); Jun LUO, Beijing (CN)

(21) Appl. No.: 18/865,447

(22) PCT Filed: Dec. 29, 2022
(86) PCT No.: PCT/CN2022/143242

§ 371 Date: Nov. 13, 2024

(30) Foreign Application Priority Data
Oct. 28, 2022 (CN) 202211335668.2

(51) Int. Cl. H10B 12/00

(52) U.S. Cl. CPC H10B 12/00

(57) ABSTRACT

The capacitor-free memory includes: a substrate; an isolation layer; a read bit line layer; a columnar first stack on an upper surface of the read bit line layer which including a first channel layer, a read word line layer, and a first hard mask layer; a first gate dielectric layer surrounding a side surface and an upper surface of the first stack, and the upper surface of the read bit line layer; a first gate layer covering a surface of the first gate dielectric layer; a columnar second stack on an upper surface of the first gate layer which including a second channel layer, a write bit line layer, and a second hard mask layer; a second gate dielectric layer surrounding a side surface of the second stack, an upper surface of the second stack, and the upper surface of the first gate layer; and a second gate layer.

### CROSS REFERENCE TO RELATED APPLICATION(S)

This application is a Section 371 National Stage Application of International Application No. PCT/CN2022/143242, filed on Dec. 29, 2022, which claims priority to Chinese Patent Application No. 202211335668.2, filed on Oct. 28, 2022 and entitled “VERTICAL GATE-ALL-AROUND TRANSISTOR AND MANUFACTURING METHOD THEREOF, AND CAPACITOR-FREE MEMORY AND MANUFACTURING METHOD THEREOF”, the entire content of which is incorporated herein in its entirety by reference.

### TECHNICAL FIELD

The present disclosure relates to a field of transistors, and in particular to a vertical gate-all-around transistor, a method of manufacturing a vertical gate-all-around transistor, a capacitor-free memory, and a method of manufacturing a capacitor-free memory.

### BACKGROUND

Amorphous Oxide-Semiconductor Thin Film Transistor (OSTFT) has great potential in fields of driver and memory for display panels as well as flexible circuits due to its low leakage current and simple low-temperature manufacturing process.

### SUMMARY

The present disclosure provides a vertical gate-all-around transistor, a method of manufacturing a vertical gate-all-around transistor, a capacitor-free memory, and a method of manufacturing a capacitor-free memory.

The first aspect of the present disclosure provides a vertical gate-all-around transistor. The vertical gate-all-around transistor includes: a substrate; an isolation layer; a source layer; a plurality of columnar first stacks on an upper surface of a read bit line layer, wherein the first stack includes a first channel layer, a read word line layer, and a first hard mask layer stacked sequentially from bottom to top; a first gate dielectric layer surrounding a side surface of the first stack, an upper surface of the first stack, and the upper surface of the read bit line layer; and a first gate layer covering a surface of the first gate dielectric layer and filling a gap between adjacent first stacks of the plurality of columnar first stacks, wherein the substrate, the isolation layer, the source layer, the plurality of columnar first stacks, the first gate dielectric layer, and the first gate layer are stacked sequentially from bottom to top.

The second aspect of the present disclosure provides a vertical gate-all-around capacitor-free memory. The vertical gate-all-around capacitor-free memory includes a substrate, an isolation layer, a lower transistor, and an upper transistor stacked sequentially from bottom to top, wherein the lower transistor includes: a read bit line layer; a plurality of columnar first stacks on an upper surface of the read bit line layer, wherein the first stack includes a first channel layer, a read word line layer, and a first hard mask layer stacked sequentially from bottom to top; a first gate dielectric layer surrounding a side surface of the first stack, an upper surface of the first stack, and the upper surface of the read bit line layer; and a first gate layer covering a surface of the first gate dielectric layer and filling a gap between adjacent first stacks of the plurality of columnar first stacks; wherein the upper transistor includes: a plurality of columnar second stacks on an upper surface of the first gate layer, wherein the second stack includes a second channel layer, a write bit line layer, and a second hard mask layer stacked sequentially from bottom to top; a second gate dielectric layer surrounding a side surface of the second stack, an upper surface of the second stack, and the upper surface of the first gate layer; and a second gate layer covering a surface of the second gate dielectric layer and filling a gap between adjacent second stacks of the plurality of columnar second stacks; and wherein the first gate layer in the lower transistor serves as a drain of the upper transistor.

Furthermore, the isolation layer includes at least one of SiO₂ or SiNₓ; and/or each of the read bit line layer, the read word line layer, the first gate layer, the write bit line layer, and the second gate layer includes at least one of Mo, TiN, Ti, Al, indium tin oxide, or indium zinc oxide.

Furthermore, each of the first channel layer and the second channel layer includes at least one of In₂O₃, ZnO, or IGZO; and/or each of the first gate dielectric layer and the second gate dielectric layer includes at least one of SiO₂, HfO₂, or Al₂O₃.

Furthermore, the first stack is conformal with the second stack.

Furthermore, the first gate dielectric layer is conformal with the second gate dielectric layer.

Furthermore, the first gate layer is conformal with the second gate layer.

The third aspect of the present disclosure provides a method of manufacturing the vertical gate-all-around transistor as described above. The method includes: providing the substrate; sequentially stacking, on the substrate, the isolation layer, the source layer, the first channel layer, the read word line layer, and the first hard mask layer from bottom to top; patterning the first hard mask layer, and etching the first channel layer and the read word line layer using the first hard mask layer as a mask, so as to form the plurality of columnar first stacks including stacked first channel layer, read word line layer, and first hard mask layer; forming the first gate dielectric layer, wherein the first gate dielectric layer surrounds the side surface of the first stack, the upper surface of the first stack, and the upper surface of the read bit line layer; and filling the gap between the adjacent first stacks with a gate material, so as to form the first gate layer.

The fourth aspect of the present disclosure provides a method of manufacturing the vertical gate-all-around capacitor-free memory. The method includes: providing the substrate; sequentially stacking, on the substrate, the isolation layer, the read bit line layer, the first channel layer, the read word line layer, and the first hard mask layer from bottom to top; patterning the first hard mask layer, and etching the first channel layer and the read word line layer using the first hard mask layer as a mask, so as to form the plurality of columnar first stacks including stacked first channel layer, read word line layer, and first hard mask layer; forming the first gate dielectric layer, wherein the first gate dielectric layer surrounds the side surface of the first stack, the upper surface of the first stack, and the upper surface of the read bit line layer; filling the gap between the adjacent first stacks with a gate material, so as to form the first gate layer; sequentially stacking, on a surface of the first gate layer, the second channel layer, the write bit line layer, and the second hard mask layer from bottom to top; patterning the second hard mask layer, and etching the second channel layer and the write bit line layer using the second hard mask layer as a mask, so as to form the plurality of columnar second stacks including stacked second channel layer, write bit line layer, and second hard mask layer; forming the second gate dielectric layer, wherein the second gate dielectric layer surrounds the side surface of the second stack, the upper surface of the second stack, and the upper surface of the first gate layer; and filling the gap between the adjacent second stacks with a gate material, so as to form the second gate layer.

Furthermore, the method further includes: after forming the first gate layer and before forming the second channel layer, depositing a dielectric material and planarizing the dielectric material, so as to expose the upper surface of the first gate layer.

Furthermore, the method further includes: leading out electrodes of the read bit line layer, the read word line layer, the first gate layer, the write bit line layer, and the second gate layer.

Furthermore, the method further includes: after forming the first gate layer and before forming the second channel layer, patterning the first gate layer.

### BRIEF DESCRIPTION OF THE DRAWINGS

Various other advantages and benefits will become clear to those ordinary skilled in the art by reading the detailed description of the preferred embodiments in the following. The accompanying drawings are only intended to illustrate preferred embodiments and are not considered a limitation of the present disclosure, and in the drawings:

FIG. 1 shows a schematic structural diagram of a dual-transistor capacitor-free dynamic random access memory in the related art;

FIG. 2 shows a schematic structural diagram of a capacitor-free memory provided by the present disclosure;

FIG. 3 shows a schematic diagram of a memory principle of the structure shown in FIG. 2; and

FIGS. 4 to 14 show schematic diagrams of structures obtained in steps of a manufacturing method provided by the present disclosure.

### DETAILED DESCRIPTION OF EMBODIMENTS

Hereinafter, embodiments of the present disclosure will be described with reference to accompanying drawings. However, it should be understood that these descriptions are illustrative and not intended to limit the scope of the present disclosure. Further, in the following, descriptions for known structures and technologies are omitted to avoid obscuring the concept of the present disclosure unnecessarily.

Various structures according to embodiments of the present disclosure are shown in the accompanying drawings. However, they are not drawn to scale, and some features may be enlarged while some features may be omitted for sake of clarity. Shapes, relative sizes and positions of regions and layers shown in the drawings are only illustrative, and deviations may occur due to manufacture tolerances or technique limitations in practice. In addition, those skilled in the art may devise regions/layers of other different shapes, sizes, and relative positions as desired in practice.

In the context of the present disclosure, when a layer/element is recited as being “on” a further layer/element, the layer/element may be disposed directly on the further layer/element, or otherwise there may be an intervening layer/element interposed therebetween. Further, if a layer/element is “on” a further layer/element in an orientation, then the layer/element may be “under” the further layer/element when the orientation is turned.

Existing devices with horizontal and vertical channels are planar devices, in which the gate only covers one side of the channel, while due to the unevenness of the surface of the back channel on the other side, it is highly likely to cause carrier scattering and diffusion of impurities such as H, resulting in a deterioration of device performance. A gate-all-around transistor with a full enclosure structure may eliminate the instability caused by the back channel.

Devices with vertical channels are considered to have a relatively small occupation area and are easier to be integrated into three-dimensional (3D) chips, making them have great potential for application in chips with high integration density. Vertical gate-all-around oxide semiconductor thin film transistors have great potential for application in single 3D stack chips due to their compatibility with back end of line.

At present, the common DRAM cell structure is a structure in which a drain of a transistor is coupled to a capacitor. For such structure, it is necessary to constantly refresh charges in the capacitor to ensure that data is not lost, and release the charges in the capacitor during reading, and then re-write the charges in the capacitor after reading, which consumes a lot of power. Meanwhile, due to the large area occupied by the manufacturing process of capacitors, size reduction has become a challenge.

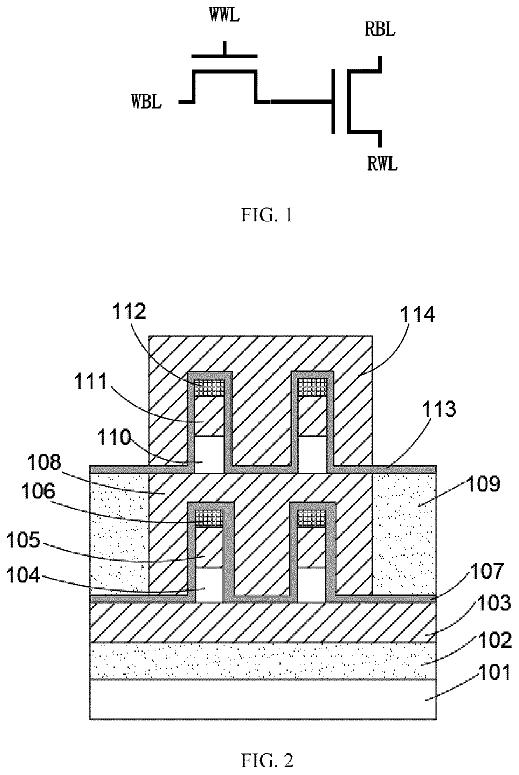

The dual-transistor capacitor-free dynamic random access memory (2 Transistor 0 Capacitor, 2T0C) uses two transistors as a cell structure, and the circuit diagram is shown in FIG. 1. The drain of one transistor is connected to the gate of the other transistor, and the gate capacitor is used to store charges and change the transconductance memory information of the transistor.

In recent years, 2T0C memory with Indium Gallium Zinc Oxide (IGZO) as the channel has been widely popular, due to the extremely low off-state current of IGZO thin film transistors (TFTs). The 2T0C DRAM cell may be used to significantly reduce the leakage speed. However, existing 2T0C DRAM cells based on IGZO TFTs generally use two TFTs with horizontal channels connected in the same plane, which occupies a relatively large area and has a lower integration density.

Existing 3D chip structures usually use 3D packaging, wafer bonding, or TSV (Through-Silicon-Via) technologies, which to some extent reduces the cell area and improves the integration density. However, due to the size limitations of the above methods, the interconnection channels between memory and logic parts are in the magnitude of several micrometers or tens of micrometers, greatly limiting the efficiency and bandwidth of 3D vertical interconnection. Additionally, due to the limitation of the aspect ratio of deep holes, the area of the hole is relatively large. In the method of single chip 3D integration, the integrated circuit processes (such as thin film, photolithography, etching, etc.) are used on the basis of existing two-dimensional chips to grow devices with specific functions. The method of single chip 3D integration may minimize the length of interconnection lines and improve the integration density to the greatest extent. Furthermore, internal interconnection may be achieved between layers, further reducing the difficulty of interconnection. One of the biggest challenges of single chip 3D integration is the low-temperature process (generally requiring less than 400° C.). IGZO-TFT may achieve the low-temperature manufacturing.

The present disclosure provides a vertical gate-all-around transistor, a method of manufacturing a vertical gate-all-around transistor, a capacitor-free memory, and a method of manufacturing a capacitor-free memory, so as to solve a problem of low integration density caused by horizontal channel in the related art, enhance the control ability of the gate on the conductive channel by using the gate-all-around transistor, control the gate width by controlling the number of nanosheets and the sizes of nanosheets, and reduce the interconnection difficulty through sharing the same electrode by the upper and lower transistors.

For example, the present disclosure provides a capacitor-free DRAM cell structure based on the thin film transistor as shown in FIG. 2. Such structure may be functionally divided into three parts from bottom to up: a substrate, a lower transistor, and an upper transistor, as follows.

A substrate 101 may be any substrate known to those skilled in the art for carrying components of semiconductor integrated circuits, such as silicon-on-insulator (SOI), bulk silicon, silicon carbide, germanium, silicon germanium, gallium arsenide, or germanium on insulator. The corresponding top semiconductor material is silicon, germanium, silicon germanium, or gallium arsenide.

An isolation layer 102 is formed on the substrate 101. The isolation layer 102 may be made of a material with high k dielectric, such as oxide, nitrogen oxide, e.g. existing silicon oxide (SiO₂), silicon oxynitride, silicon nitride (SiNₓ), etc.

The lower transistor is located on the isolation layer 102. The lower transistor is a vertical stack for achieving the read function. The lower transistor includes a read bit line layer 103 (i.e. the source of the lower transistor) that covers a large area of the isolation layer, a first stack, a first gate dielectric layer 107 and a first gate layer 108.

A plurality of columnar first stacks are provided on the upper surface of the read bit line layer 103. The first stack includes a first channel layer 104, a read word line layer 105, and a first hard mask layer 106 stacked sequentially from bottom to top. The read bit line layer 103 is not patterned into nanosheets as the first channel layer 104, mainly for enhancing the isolation effect of the gate dielectric on the first channel layer 104 and enhancing the control ability of the gate on the first channel layer 104. The read word line layer 105 is the drain. The first hard mask layer 106 is retained mainly for etching to form a stack of the nanosheet. The first gate dielectric layer 107 surrounds the side surface of the first stack, the upper surface of the first stack, and the upper surface of the read bit line layer 103, playing a good isolation role. The first gate layer 108 covers the surface of the first gate dielectric layer 107 and fills the gap between adjacent first stacks. Such gate-all-around formation has the characteristics of small space occupation and large gate width, and stronger control ability on the channel. The first gate layer 108 in the lower transistor is also the drain of the upper transistor, that is, the lower transistor shares the same electrode with the upper transistor.

The upper transistor is also a vertical stack to achieve a writing function. The upper transistor includes a second stack, a second gate dielectric layer 113, and a second gate layer 114.

A plurality of columnar second stacks are provided on the upper surface of the first gate layer 108. The second stack includes a second channel layer 110, a write bit line layer 111, and a second hard mask layer 112 stacked sequentially from bottom to top. The second gate dielectric layer 113 surrounds the side surface of the second stack, the upper surface of the second stack, and the upper surface of the first gate layer 108, playing a good isolation role. The second gate layer 114 covers the surface of the second gate dielectric layer 113 and fills the gap between adjacent second stacks. Such gate-all-around formation has the characteristics of small space occupation and large gate width, and stronger control ability on the channel. In addition, the first gate layer 108 and the second gate layer 114 may be patterned to have a predetermined shape. The gap generated by patterning may be filled with the dielectric material, such as a dielectric filling layer 109 shown in FIG. 2.

The capacitor-free memory shown in FIG. 2 has the following characteristics.
(1) Two transistors are stacked vertically. The bit line, the word line, the gate, and the channel in each transistor are also stacked vertically. The above multiple three-dimensional stacking greatly reduces the cell area and increases the integration density.
(2) The gates (the first gate layer and the second gate layer) in two transistors adopt the “gate-all-around” structure, which surrounds the channel and the source/drain, and fills the gap between adjacent stacks (i.e. the nanosheet structure includes the channel and the source/drain). The gate width is indirectly increased by using the gap, so that the channel is strongly controlled, thereby reducing the sub threshold swing and the off-state current.
(3) The gates (the first gate layer and the second gate layer) in two transistors adopt the “gate-all-around” structure, which may surround the entire channels, thereby avoiding the adverse effects of the back channel on the transistors.
(4) The number and size of nanosheet structures such as the first stack and the second stack may be freely adjusted during the patterning and etching stages, and thus the gate width may also be adjusted accordingly, with almost no effect on the integrated density.

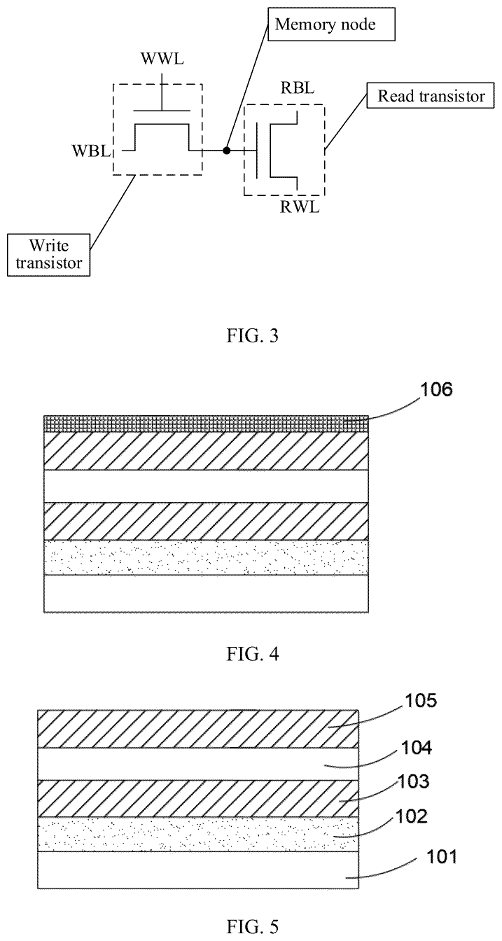

The operating principle of the capacitor-free memory of the present disclosure described above is shown in FIG. 3 (the position of the transistor in the figure is only for the convenience of illustrating the operating principle and does not represent the actual position arrangement). The first-layer transistor serves as the read transistor, and the second-layer transistor serves as the write transistor. The gate of the first-layer transistor and the drain of the second-layer transistor are the same electrode. The charges in the gate capacitor of the read transistor are changed through the write transistor, and thus the resistance state between the source and drain of the read transistor is affected, thereby achieving the distinction between “0” and “1”. The specific principle is as follows.

In the process of writing “1”, a positive voltage (greater than the threshold voltage Vth) is applied to the write word line WWL to turn on the write transistor, and a positive voltage is applied to the write bit line WBL to inject charges into the gate capacitor (i.e. memory node) of the read transistor. After charge injection, the voltages on the gate and source of the write transistor are removed, and the “1” state is saved.

In the process of reading “1”, a read voltage is applied to the drain of the read transistor. As there are some charges in the gate capacitor, the read transistor is in a lower resistance state, so as to obtain a relatively large current. After being amplified and recognized by the peripheral circuit, the process of reading “1” is completed.

In the process of writing “0”, a positive voltage (greater than the threshold voltage Vth) is applied to the gate of the read transistor to turn on the write transistor, and a negative voltage is applied to the source of the write transistor to extract charges from the gate capacitor (i.e. memory node) of the read transistor. After charge extraction, the voltages on the gate and source of the write transistor are removed, and the “0” state is saved.

In the process of reading “0”, a read voltage is applied to the drain of the read transistor. As there is no charge in the gate capacitor, the read transistor is in a higher resistance state, so as to obtain a relatively small current. After being amplified and recognized by the peripheral circuit, the process of reading “0” is completed.

In terms of material selection, any layer in the above capacitor-free memory may be made of any material that may achieve its basic functions. However, in order to further improve the electrical performance and usability of the memory, each layer has its preferred material.

For example, each of the first channel layer 104 and the second channel layer 110 includes at least one of In₂O₃, ZnO, or IGZO. As the off-state leakage of the IGZO thin film transistor is very low, the information at the memory node may be maintained for a long time.

The first gate dielectric layer 107 and the second gate dielectric layer 113 serve as insulation between the gate and the channel. Materials with wide bandgap and high dielectric constant or materials suitable for fabricating extremely small devices are preferred for the first gate dielectric layer 107 and the second gate dielectric layer 113, such as at least one of SiO₂, HfO₂, or Al₂O₃.

The read bit line layer 103, the read word line layer 105, the first gate layer 108, the write bit line layer 111, and the second gate layer 114 serve as electrodes to be connected to the power supply. Metal materials or doped semiconductor materials with good conductivity, including but not limited to at least one of Mo, TiN, Ti, Al, W, indium tin oxide, or indium zinc oxide, are preferred for the read bit line layer 103, the read word line layer 105, the first gate layer 108, the write bit line layer 111, and the second gate layer 114. In addition, considering the fast and stable current transmission between electrodes, the read bit line layer 103, the read word line layer 105, the first gate layer 108, the write bit line layer 111, and the second gate layer 114 are preferably made of the same material or materials with similar properties.

The capacitor-free memory of the present disclosure has superior levels compared to memories in the related art in terms of the integrated density, the control ability of the gate on the conductive channel, and adjustable gate width due to specific structural characteristics. The specific structural characteristics of the capacitor-free memory of the present disclosure are mainly reflected in the following aspects.

In an aspect, two transistors are stacked vertically. The bit line, the word line, the gate, and the channel in each transistor are also stacked vertically. The above multiple three-dimensional stacking greatly reduces the cell area and increases the integration density.

In another aspect, the gates (the first gate layer and the second gate layer) in two transistors adopt the “gate-all-around” structure, which surrounds the channel and the source/drain, and fills the gap between adjacent stacks (i.e. the nanosheet structure includes the channel and the source/drain). The gate width is indirectly increased by using the gap, so that the channel is strongly controlled, thereby reducing the sub threshold swing and the off-state current.

In another aspect, the number and size of nanosheet structures such as the first stack and the second stack may be freely adjusted during the patterning and etching stages, and thus the gate width may also be adjusted accordingly, with almost no effect on the integrated density.

In another aspect, the gates (the first gate layer and the second gate layer) in two transistors adopt the “gate-all-around” structure, which may surround the entire channels, thereby avoiding the adverse effects of the back channel on the transistors.

In another aspect, the gate of the lower transistor and the drain of the upper transistor use the same electrode (i.e. the gate of the lower transistor serves as the drain of the upper transistor), further reducing the interconnection difficulty and the parasitic effect.

The present disclosure further provides a method of manufacturing the capacitor-free memory as described above, which has a simple process and good compatibility with existing 3D semiconductor device processing techniques. With reference to FIGS. 4 to 14 and FIG. 2, the specific process is described as follows.

An isolation layer 102 is formed on the surface of the semiconductor substrate 101 as shown in FIG. 4. As described above, the isolation layer 102 is preferably made of silicon oxide, which may be deposited by using deposition methods such as in-situ oxidation, PECVD, and ALCVD.

Next, metal is sputtered or other electrode material layers are grown on the surface of the isolation layer 102 as a read bit line layer 103.

Then, a first channel layer 104 is formed on the surface of the read bit line layer 103.

Next, a conductive material is deposited on the upper surface of the first channel layer 104 to form a read word line layer 105, as shown in FIG. 4.

A hard mask material is grown on the upper surface of the read word line layer 105, so as to form a first hard mask layer 106, as shown in FIG. 5.

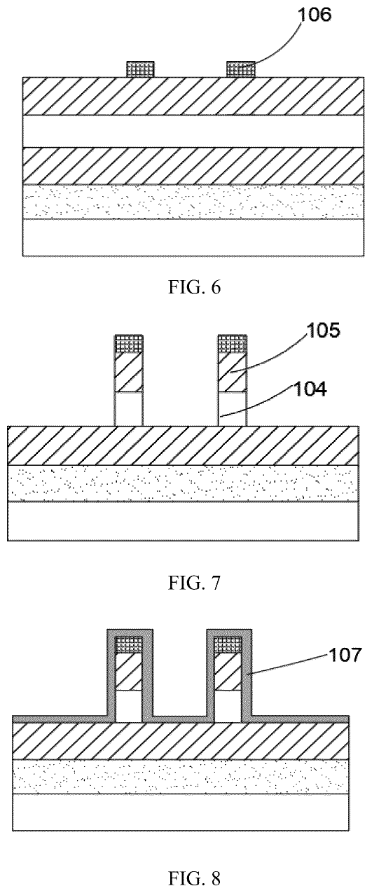

The first hard mask layer 106 is patterned according to the predetermined nanosheet structure, as shown in FIG. 6. Only two nanosheets are illustrated in the figure, but the number of nanosheets is not limited in the present disclosure. The number of nanosheets may be adjusted arbitrarily in the actual process.

The first channel layer 104 and the read word line layer 105 are etched by using the first hard mask layer 106 shown in FIG. 6 as the mask, so as to form a plurality of columnar first stacks including stacked first channel layer 104, read word line layer 105, and first hard mask layer 106, as shown in FIG. 7.

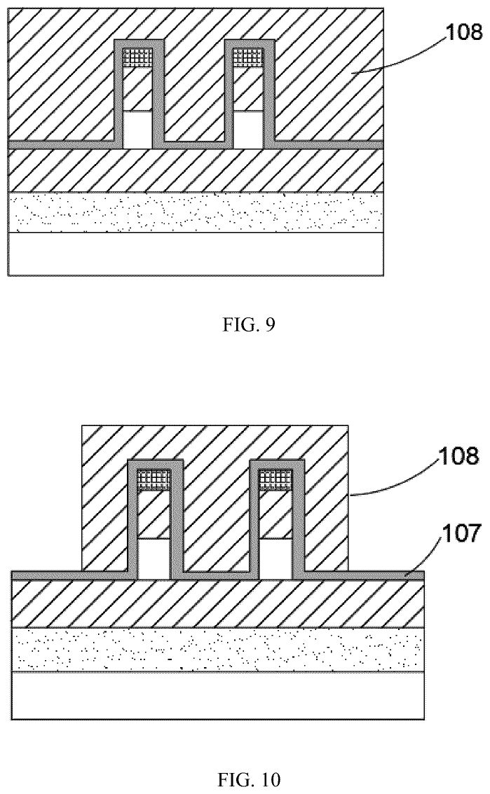

Next, a first gate dielectric layer 107 is grown. The first gate dielectric layer 107 surrounds the side surface of the first stack, the upper surface of the first stack, and the upper surface of the read bit line layer 103, as shown in FIG. 8.

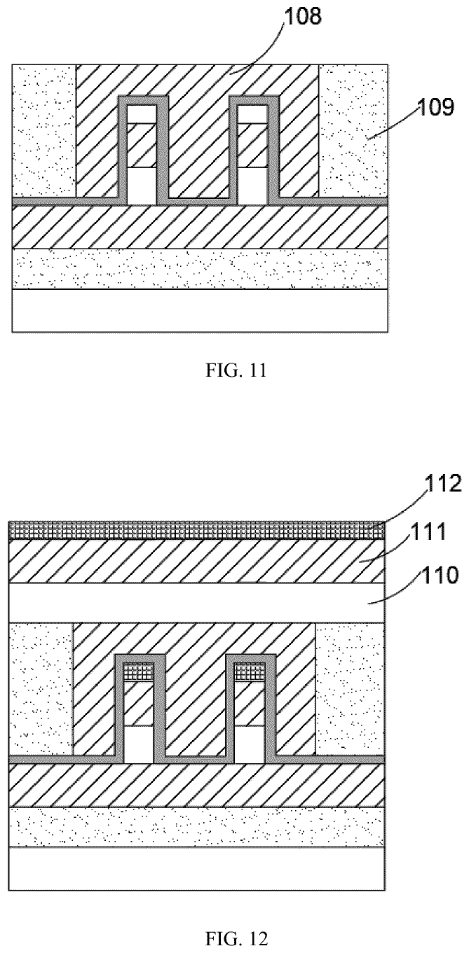

The gap between adjacent first stacks is filled with the gate material to form the first gate layer 108, as shown in FIG. 9. Usually, the first gate layer 108 is patterned to partially expose the first gate dielectric layer 107 that covers the read bit line layer, thereby better isolating from the read bit line layer 103, as shown in FIG. 10. The cavity formed after patterning may be filled with a dielectric material, such as the dielectric filling layer 109 shown in FIG. 11.

Then, a second channel layer 110, a write bit line layer 111, and a second hard mask layer 112 are sequentially stacked from bottom to top on the surface of the first gate layer 108, as shown in FIG. 12.

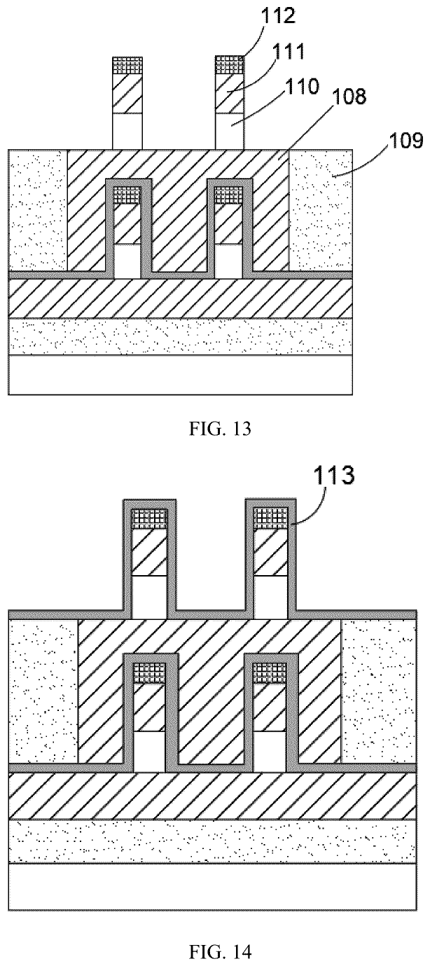

Next, the same process as the first stack is used. The second hard mask layer 112 is patterned according to the predetermined nanosheet structure. Then, the second channel layer 110 and the write bit line layer 111 are etched by using the second hard mask layer 112 as the mask, so as to form a plurality of columnar second stacks including stacked second channel layer 110, write bit line layer 111, and second hard mask layer 112, as shown in FIG. 13. In some preferred embodiments, the second stack is conformal with the first stack, but this does not limit the maximum protection scope of the present disclosure.

Then, a second gate dielectric layer 113 is grown. The second gate dielectric layer 113 surrounds the side surface of the second stack, the upper surface of the second stack, and the upper surface of the first gate layer 108, as shown in FIG. 14. In some preferred embodiments, the second gate dielectric layer 113 is conformal with the first gate dielectric layer 107, but this does not limit the maximum protection scope of the present disclosure.

The gap between adjacent second stacks is filled with the gate material to form the second gate layer 114. Similarly, the second gate layer 114 is patterned to obtain the structure shown in FIG. 2. In some preferred embodiments, the second gate layer 114 is conformal with the first gate layer 108, but this does not limit the maximum protection scope of the present disclosure.

Then, any large-area deposited dielectric material is used for filling, and then methods such as photoetching contact holes or etching step structures are used to lead out the electrode of each conductive layer.

In view of above, compared with the related art, the present disclosure achieves the following technical effects.
(1) In the present disclosure, the gate-all-around transistor is used to enhance the control ability of the gate on the conductive channel, reduce the sub threshold swing, and decrease the off-state current.
(2) In the present disclosure, the gate width is controlled by controlling the number and size of nanosheets, so as to meet different usage desires.
(3) In the present disclosure, three-dimensional integration is achieved through vertical stacking, further reducing the cell area and increasing the integration density.
(4) The gate of the lower transistor and the drain of the upper transistor use the same electrode, further reducing the interconnection difficulty and the parasitic effect.
(5) The manufacturing method provided by the present disclosure has a simple process and low requirements for devices and operating conditions.

Embodiments of the present disclosure have been described above. However, these embodiments are for illustrative purposes only, and are not intended to limit the scope of the present disclosure. The scope of the present disclosure is defined by the appended claims and their equivalents. Without departing from the scope of the present disclosure, those skilled in the art may make various substitutions and modifications, and these substitutions and modifications should all fall within the scope of the present disclosure.

1. A vertical gate-all-around transistor, comprising:
a substrate;
an isolation layer;
a source layer;
a plurality of columnar first stacks on an upper surface of a read bit line layer, wherein the first stack comprises a first channel layer, a read word line layer, and a first hard mask layer stacked sequentially from bottom to top;
a first gate dielectric layer surrounding a side surface of the first stack, an upper surface of the first stack, and the upper surface of the read bit line layer; and
a first gate layer covering a surface of the first gate dielectric layer and filling a gap between adjacent first stacks of the plurality of columnar first stacks, wherein the substrate, the isolation layer, the source layer, the plurality of columnar first stacks, the first gate dielectric layer, and the first gate layer are stacked sequentially from bottom to top.

2. A vertical gate-all-around capacitor-free memory, comprising a substrate, an isolation layer, a lower transistor, and an upper transistor stacked sequentially from bottom to top,
wherein the lower transistor comprises:
a read bit line layer;
a plurality of columnar first stacks on an upper surface of the read bit line layer, wherein the first stack comprises a first channel layer, a read word line layer, and a first hard mask layer stacked sequentially from bottom to top;
a first gate dielectric layer surrounding a side surface of the first stack, an upper surface of the first stack, and the upper surface of the read bit line layer; and
a first gate layer covering a surface of the first gate dielectric layer and filling a gap between adjacent first stacks of the plurality of columnar first stacks;
wherein the upper transistor comprises:
a plurality of columnar second stacks on an upper surface of the first gate layer, wherein the second stack comprises a second channel layer, a write bit line layer, and a second hard mask layer stacked sequentially from bottom to top;
a second gate dielectric layer surrounding a side surface of the second stack, an upper surface of the second stack, and the upper surface of the first gate layer; and
a second gate layer covering a surface of the second gate dielectric layer and filling a gap between adjacent second stacks of the plurality of columnar second stacks; and
wherein the first gate layer in the lower transistor serves as a drain of the upper transistor.

3. The vertical gate-all-around capacitor-free memory according to claim 12, wherein the isolation layer comprises at least one of SiO₂ or SiNₓ; and/or
wherein each of the read bit line layer, the read word line layer, the first gate layer, the write bit line layer, and the second gate layer comprises at least one of Mo, TiN, Ti, or Al.

4. The vertical gate-all-around capacitor-free memory according to claim 2, wherein each of the first channel layer and the second channel layer comprises at least one of In₂O₃, ZnO, or IGZO; and/or
wherein each of the first gate dielectric layer and the second gate dielectric layer comprises at least one of SiO₂, HfO₂, or Al₂O₃.

5. The vertical gate-all-around capacitor-free memory according to claim 2, wherein the first stack is conformal with the second stack.

6. The vertical gate-all-around capacitor-free memory according to claim 2, wherein the first gate dielectric layer is conformal with the second gate dielectric layer.

7. The vertical gate-all-around capacitor-free memory according to claim 2, wherein the first gate layer is conformal with the second gate layer.

8. A method of manufacturing the vertical gate-all-around transistor of claim 1, comprising:
providing the substrate;
sequentially stacking, on the substrate, the isolation layer, the source layer, the first channel layer, the read word line layer, and the first hard mask layer from bottom to top;
patterning the first hard mask layer, and etching the first channel layer and the read word line layer using the first hard mask layer as a mask, so as to form the plurality of columnar first stacks comprising stacked first channel layer, read word line layer, and first hard mask layer;
forming the first gate dielectric layer, wherein the first gate dielectric layer surrounds the side surface of the first stack, the upper surface of the first stack, and the upper surface of the read bit line layer; and
filling the gap between the adjacent first stacks with a gate material, so as to form the first gate layer.

9. A method of manufacturing the vertical gate-all-around capacitor-free memory of claim 2, comprising:
providing the substrate;
sequentially stacking, on the substrate, the isolation layer, the read bit line layer, the first channel layer, the read word line layer, and the first hard mask layer from bottom to top;
patterning the first hard mask layer, and etching the first channel layer and the read word line layer using the first hard mask layer as a mask, so as to form the plurality of columnar first stacks comprising stacked first channel layer, read word line layer, and first hard mask layer;
forming the first gate dielectric layer, wherein the first gate dielectric layer surrounds the side surface of the first stack, the upper surface of the first stack, and the upper surface of the read bit line layer;
filling the gap between the adjacent first stacks with a gate material, so as to form the first gate layer;
sequentially stacking, on a surface of the first gate layer, the second channel layer, the write bit line layer, and the second hard mask layer from bottom to top;
patterning the second hard mask layer, and etching the second channel layer and the write bit line layer using the second hard mask layer as a mask, so as to form the plurality of columnar second stacks comprising stacked second channel layer, write bit line layer, and second hard mask layer;
forming the second gate dielectric layer, wherein the second gate dielectric layer surrounds the side surface of the second stack, the upper surface of the second stack, and the upper surface of the first gate layer; and
filling the gap between the adjacent second stacks with a gate material, so as to form the second gate layer.

10. The method according to claim 9, further comprising: after forming the first gate layer and before forming the second channel layer,
depositing a dielectric material and planarizing the dielectric material, so as to expose the upper surface of the first gate layer.

11. The method according to claim 9, further comprising:
leading out electrodes of the read bit line layer, the read word line layer, the first gate layer, the write bit line layer, and the second gate layer.

12. The method according to claim 9, further comprising: after forming the first gate layer and before forming the second channel layer,
patterning the first gate layer.
